(19) United States
(12) Patent Application Publication
(10) Pub. No.: US 2011/0114177 A1
(43) Pub. Date: May 19, 2011

(54) MIXED SILICON PHASE FILM FOR HIGH EFFICIENCY THIN FILM SILICON SOLAR CELLS

(75) Inventors: Fan Yang, Sunnyvale, CA (US); Lin Zhang, San Jose, CA (US); Yi Zheng, Sunnyvale, CA (US); Francimar Schmitt, Santa Clara, CA (US); Zheng Yuan, Cupertino, CA (US)

(73) Assignee: APPLIED MATERIALS, INC., Santa Clara, CA (US)

(21) Appl. No.: 12/838,861

(22) Filed: Jul. 19, 2010

Related U.S. Application Data
(60) Provisional application No. 61/227,844, filed on Jul. 23, 2009.

(51) Int. Cl. H01L 31/0264; H01L 31/0376; H01L 31/20

(52) U.S. Cl. 136/258; 438/96; 257/E31.048

(57) ABSTRACT

A method and apparatus for forming solar cells is provided. In one embodiment, a photovoltaic device includes a first p-i-n junction cell formed on a substrate, wherein the p-i-n junction cell comprises a p-type silicon containing layer, an intrinsic type silicon containing layer formed over the p-type silicon containing layer, and a n-type silicon containing layer formed over the intrinsic type silicon containing layer, wherein the intrinsic type silicon containing layer comprises a first pair of microcrystalline layer and amorphous silicon layer.

### CROSS-REFERENCE TO RELATED APPLICATIONS

This application claims benefit of U.S. Provisional Application Ser. No. 61/227,844 filed Jul. 23, 2009 (Attorney Docket No. APPM/14139L), which is incorporated by reference in their entirety.

### BACKGROUND OF THE INVENTION

1. Field of the Invention

Embodiments of the present invention generally relate to solar cells and methods for forming the same. More particularly, embodiments of the present invention relate to an intrinsic type silicon layer having mixed silicon phases formed in thin-film and crystalline solar cells.

2. Description of the Related Art

Crystalline silicon solar cells and thin film solar cells are two types of solar cells. Crystalline silicon solar cells typically use either mono-crystalline substrates (i.e., single-crystal substrates of pure silicon) or multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-n junctions. Suitable substrates include glass, metal, and polymer substrates.

To expand the economic use of solar cells, efficiency must be improved. Solar cell efficiency relates to the proportion of incident radiation converted into useful electricity. To be useful for more applications, solar cell efficiency must be improved panel efficiencies of approximately 10%. With the increase of energy cost as well as environmental concerns, there is a need for more efficient thin film solar cells. The methods and apparatuses for manufacturing these solar cell is thus of substantially business opportunities and environmental significance.

### SUMMARY OF THE INVENTION

Embodiments of the invention provide methods of forming solar cells. In one embodiment, a photovoltaic device includes a first p-i-n junction cell formed on a substrate, wherein the p-i-n junction cell comprises a p-type silicon containing layer, an intrinsic type silicon containing layer formed over the p-type silicon containing layer, and a n-type silicon containing layer formed over the intrinsic type silicon containing layer, wherein the intrinsic type silicon containing layer comprises a first pair of microcrystalline layer and amorphous silicon layer.

In another embodiment, a method for forming a photovoltaic device including providing a substrate into a processing chamber, depositing a multilayered intrinsic layer on the substrate by a method comprising supplying a gas mixture to the processing chamber, applying a RF power to the processing chamber at a first power range to form a first intrinsic type microcrystalline silicon layer over the substrate, and adjusting the RF power to a second power range to form a first intrinsic type amorphous silicon layer over the first intrinsic type microcrystalline silicon layer.

In yet another embodiment, a photovoltaic device having a p-i-n junction cell formed on a substrate, wherein the p-i-n junction includes a p-type silicon containing layer, an intrinsic type silicon containing layer and a n-type silicon containing layer, the photovoltaic device including an intrinsic type silicon containing layer having interleaved adjacent intrinsic microcrystalline silicon layers and intrinsic amorphous silicon layers.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic side-view of a single junction thin-film solar cell according to one embodiment of the invention;

FIG. 2 depicts an enlarged view of an intrinsic type silicon containing layer of the single junction thin-film solar cell of FIG. 1;

FIG. 3 depicts an enlarged view of a grain distribution of the intrinsic type silicon containing layer of the single junction thin-film solar cell of FIG. 1;

FIG. 4 depicts a schematic side-view of a tandem junction thin-film solar cell according to one embodiment of the invention;

FIG. 5 depicts a schematic side-view of a triple junction thin-film solar cell according to one embodiment of the invention;

FIG. 6 depicts a cross-sectional view of an apparatus according to one embodiment of the invention; and

FIG. 7 depicts a flow diagram of a process sequence for fabricating an intrinsic type silicon containing layer having mixed phases in accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Thin-film solar cells are generally formed from numerous types of films, or layers, put together in many different ways. Most films used in such devices incorporate a semiconductor element that may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, conductivity, thickness and roughness. Most of these films can be formed by use of a chemical vapor deposition process, which may include some degree of ionization or plasma formation.

Charge generation during a photovoltaic process is generally provided by a bulk semiconductor layer, such as a silicon containing layer. The bulk layer is also sometimes called an intrinsic layer to distinguish it from the various doped layers present in the solar cell. The intrinsic layer may have any desired degree of crystallinity, which will influence its light-absorbing characteristics. For example, an amorphous intrinsic layer, such as amorphous silicon, will generally absorb light at different wavelengths compared to intrinsic layers having different degrees of crystallinity, such as microcrystalline or nanocrystalline silicon. For this reason, it is advantageous to use both types of layers to yield the broadest possible absorption characteristics.

Silicon and other semiconductors can be formed into solids having varying degrees of crystallinity. Solids having essentially no crystallinity are amorphous, and silicon with negligible crystallinity is referred to as amorphous silicon. Completely crystalline silicon is referred to as crystalline, polycrystalline, or monocrystalline silicon. Polycrystalline silicon is crystalline silicon including numerous crystal grains separated by grain boundaries. Monocrystalline silicon is a single crystal of silicon. Solids having partial crystallinity, that is a crystal fraction between about 5% and about 95%, are referred to as nanocrystalline or microcrystalline, generally referring to the size of crystal grains suspended in an amorphous phase. Solids having larger crystal grains are referred to as microcrystalline, whereas those with smaller crystal grains are nanocrystalline. It should be noted that the term “crystalline silicon” may refer to any form of silicon having a crystal phase, including microcrystalline, nanocrystalline, monocrystalline and polycrystalline silicon.

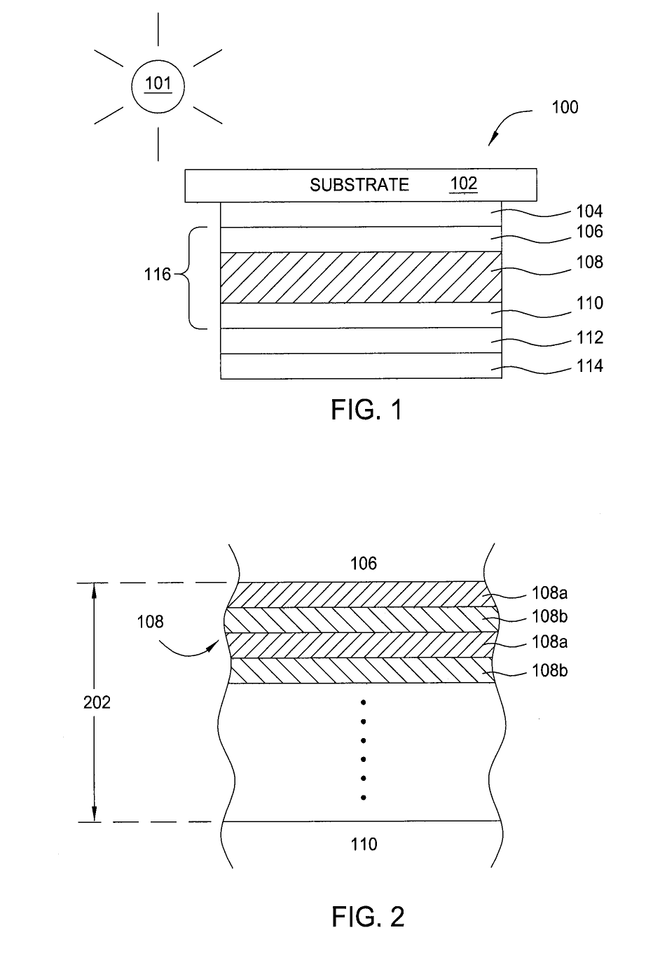

FIG. 1 is a schematic diagram of an embodiment of a single junction solar cell 100 oriented toward a light or solar radiation 101. The solar cell 100 includes a substrate 102. A first transparent conducting oxide (TCO) layer 104 formed over the substrate 102, a first p-i-n junction 116 formed over the first TCO layer 104. A second TCO layer 112 is formed over the first p-i-n junction 116, and a metal back layer 114 is formed over the second TCO layer 112. The substrate 102 may be a glass substrate, polymer substrate, or other suitable substrate, with thin films formed thereover.

The first TCO layer 104 and the second TCO layer 112 may each comprise tin oxide, zinc oxide, indium tin oxide, cadmium stannate, combinations thereof, or other suitable materials. It is understood that the TCO materials may also additionally include dopants and other components. For example, zinc oxide may further include dopants, such as tin, aluminum, gallium, boron, and other suitable dopants. In certain instances, the substrate 102 may be provided by the glass manufacturers with the first TCO layer 104 already deposited thereon.

To improve light absorption by enhancing light trapping, the substrate 102 and/or one or more of thin films formed may be optionally textured by wet, plasma, ion, and/or mechanical texturing process. For example, in the embodiment shown in FIG. 1, the first TCO layer 104 may be textured (not shown) so that the topography of the surface is substantially transferred to the subsequent thin films deposited thereafter.

The first p-i-n junction 116 may comprise a p-type silicon containing layer 106, an intrinsic type silicon containing layer 108 formed over the p-type silicon containing layer 106, and an n-type silicon containing layer 110 formed over the intrinsic type silicon containing layer 108. In certain embodiments, the p-type silicon containing layer 106 is a p-type amorphous or microcrystalline silicon layer having a thickness between about 60 Å and about 300 Å. In certain embodiments, the intrinsic type silicon containing layer 108 is an intrinsic type amorphous and microcrystalline mixed silicon layer having a thickness between about 500 Å and about 2 μm. Details regarding the fabrication of the intrinsic type silicon containing layer 108 will be further discussed below with referenced to FIGS. 2-3 and 7. In certain embodiments, the n-type silicon containing layer 110 is a n-type microcrystalline silicon layer may be formed to a thickness between about 100 Å and about 400 Å.

The metal back layer 114 may include, but not limited to a material selected from the group consisting of Al, Ag, Ti, Cr, Au, Cu, Pt, alloys thereof, and combinations thereof. Other processes may be performed to form the solar cell 100, such as a laser scribing processes. Other films, materials, substrates, and/or packaging may be provided over metal back layer 120 to complete the solar cell device. The formed solar cells may be interconnected to form modules, which in turn can be connected to form arrays.

Solar radiation 101 is primarily absorbed by the intrinsic layers 108 of the first p-i-n junction 116 and is converted to electron-holes pairs. The electric field created between the p-type layer 106 and the n-type layer 110 that extends across the intrinsic layer 108 causes electrons to flow toward the n-type layers 110 and holes to flow toward the p-type layers 106 creating a current. The intrinsic type silicon containing layer 108 of the first p-i-n junction 116 may have mixed silicon phases, e.g., combinations of amorphous and crystalline silicon phases (microcrystalline or nanocrystalline silicon phases), to take advantage of the properties of amorphous silicon and crystalline silicon which absorb different wavelengths of the solar radiation 101. By controlling the mixing ratio of the two phases, the formed solar cell 100 is more efficient, as it captures a larger portion of the solar radiation spectrum. Since the different silicon containing layers have different bandgaps, the combination used to absorb different wavelengths of light, thereby improving photocurrent generated in the cell 100.

As different silicon phases of the silicon containing layers may have different bandgap, by utilizing an intrinsic type silicon containing layer 108 having mixed silicon phases may assist absorbing different lights having different spectrums, thereby improving photocurrent generated in the cell 100.

Charge collection is generally provided by doped semiconductor layers, such as silicon layers doped with p-type or n-type dopants. In silicon based layers, p-type dopants are generally Group III elements, such as boron or aluminum while n-type dopants are generally Group V elements, such as phosphorus, arsenic, or antimony. In most embodiments, boron is used as the p-type dopant and phosphorus as the n-type dopant. These dopants may be added to the p-type and n-type layers 106, 110 respectively described above by including boron-containing or phosphorus-containing compounds in the reaction mixture. Suitable boron and phosphorus compounds generally comprise substituted and unsubstituted lower borane and phosphine oligomers. Some suitable boron containing dopant compounds include trimethylboron (B(CH₃)₃ or TMB), diborane (B₂H₆), boron trifluoride (BF₃), and triethylboron (B(C₂H₅)₃ or TEB). Phosphine (PH₃) is the most common phosphorus containing dopant compound. The dopants are generally provided with a carrier gas, such as hydrogen, helium, argon, or other suitable gas. If hydrogen is used as the carrier gas, the total hydrogen in the reaction mixture is increased. Thus, the hydrogen ratios discussed below will include the portion of hydrogen contributed carrier gas used to deliver the dopants.

Dopants will generally be provided as dilutants in an inert gas or carrier gas. For example, dopants may be provided at molar or volume concentrations of about 0.5% or less in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, the dopant concentration in the formed layer is maintained between about 10¹⁸ atoms/cm³ and about 10²⁰ atoms/cm³ of the doped silicon layers 106, 110.

In one embodiment wherein the p-type silicon containing layer 106 is a p-type microcrystalline silicon layer, the p-type microcrystalline silicon layer may be deposited by providing a gas mixture of hydrogen gas and silane gas in flow rate ratio by volume of hydrogen-to-silane of about 200:1 or greater, such as 1000:1 or less, for example between about 250:1 and about 800:1, and in a further example about 601:1 or about 401:1. Silane gas may be provided at a flow rate between about 0.1 sccm/L and about 0.8 sccm/L, such as between about 0.2 sccm/L and about 0.38 sccm/L. Hydrogen gas may be provided at a flow rate between about 60 sccm/L and about 500 sccm/L, such as about 143 sccm/L. TMB may be provided at a flow rate between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. Applying RF power between about 50 mW/cm² and about 700 mW/cm², such as between about 290 mW/cm² and about 440 mW/cm², at a chamber pressure between about 1 Torr and about 100 Torr, such as between about 3 Torr and about 20 Torr, between 4 Torr and about 12 Torr, or about 7 Torr or about 9 Torr, will deposit a p-type microcrystalline layer having crystalline fraction between about 20 percent and about 80 percent, such as between 50 percent and about 70 percent for a microcrystalline layer, at about 10 Å/min or more, such as about 143 Å/min or more.

In one embodiment wherein the p-type silicon containing layer 106 is a p-type amorphous silicon layer, the p-type amorphous silicon layer may be deposited by providing a gas mixture of hydrogen gas to silane gas in a flow rate ratio by volume of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. Applying RF power between about 15 mWatts/cm² and about 200 mWatts/cm² at a chamber pressure between about 0.1 Torr and 20 Torr, such as between about 1 Torr and about 4 Torr, will deposit a p-type amorphous silicon layer at about 100 Å/min or more. The addition of methane or other carbon containing compounds, such as CH₄, C₃H₈, C₄H₁₀, or C₂H₂, can be used to form a carbon containing p-type amorphous silicon layer that is conductive and absorbs less light than other silicon containing materials. In other words, in the configuration where the formed p-type silicon layer 106 is amorphous and contains alloying elements, such as carbon, the formed layer will have improved light transmission properties, or window properties (e.g., having lower absorption of solar radiation). The increase in the amount of solar radiation transmitted through a p-type amorphous silicon layer 106 can be absorbed by the intrinsic layers, thus improving the efficiency of the solar cell. In the embodiment wherein trimethylboron is used to provide boron dopants in the p-type amorphous silicon layer 106, the boron dopant concentration is maintained at between about 1×10¹⁸ atoms/cm³ and about 1×10²⁰ atoms/cm³. In an embodiment wherein methane gas is added and used to form a carbon containing p-type amorphous silicon layer, a carbon concentration in the carbon containing p-type amorphous silicon layer is controlled to between about 10 atomic percent and about 20 atomic percent. In one embodiment, the p-type amorphous silicon layer 106 has a thickness between about 20 Å and about 300 Å, such as between about 80 Å and about 200 Å.

In one embodiment wherein the n-type silicon containing layer 110 is a n-type microcrystalline silicon layer, the n-type microcrystalline silicon layer 110 may be deposited by providing a gas mixture of hydrogen gas to silane gas in a flow rate ratio by volume of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. Applying RF power between about 100 mW/cm² and about 900 mW/cm², such as about 370 mW/cm², at a chamber pressure of between about 1 Torr and about 100 Torr, such as between about 3 Torr and about 20 Torr, more preferably between 4 Torr and about 12 Torr, for example about 6 Torr or about 9 Torr, will deposit an n-type microcrystalline silicon layer having a crystalline fraction between about 20 percent and about 80 percent, such as between 50 percent and about 70 percent, at a rate of about 50 Å/min or more, such as about 150 Å/min or more.

In one embodiment wherein the n-type silicon containing layer 110 is a n-type amorphous silicon layer, the n-type amorphous silicon layer 110 may be deposited by providing a gas mixture of hydrogen gas to silane gas in a flow rate ratio by volume of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. Applying RF power between about 25 mW/cm² and about 250 mW/cm², such as about 60 mW/cm² or about 80 mW/cm², at a chamber pressure between about 0.1 Torr and about 20 Torr, such as between about 0.5 Torr and about 4 Torr, or about 1.5 Torr, will deposit an n-type amorphous silicon layer at a rate of about 100 Å/min or more, such as about 200 Å/min or more, such as about 300 Å/min or about 600 Å/min.

In some embodiments, alloys of silicon with other elements such as oxygen, carbon, nitrogen, hydrogen, and germanium may be added to one or more of the deposited layers. These other elements may be added to silicon films by supplementing the reactant gas mixture with sources of each. Alloys of silicon may be used in any type of silicon layers, including p-type and n-type or intrinsic type silicon layers. For example, carbon may be added to the silicon films by adding a carbon source such as methane (CH₄) to the gas mixture. In general, most C₁-C₄ hydrocarbons may be used as carbon sources. Alternately, organosilicon compounds, such as organosilanes, organosiloxanes, organosilanols, and the like may serve as both silicon and carbon sources. Germanium compounds such as germanes and organogermanes, along with compounds comprising silicon and germanium, such as silylgermanes or germylsilanes, may serve as germanium sources. Oxygen gas (O₂) may serve as an oxygen source. Other oxygen sources include, but are not limited to, oxides of nitrogen (nitrous oxide—N₂O, nitric oxide—NO, dinitrogen trioxide—N₂O₃, nitrogen dioxide—NO₂, dinitrogen tetroxide—N₂O₄, dinitrogen pentoxide—N₂O₅, and nitrogen trioxide—NO₃), hydrogen peroxide (H₂O₂), carbon monoxide or dioxide (CO or CO₂), ozone (O₃), oxygen atoms, oxygen radicals, and alcohols (ROH, where R is any organic or hetero-organic radical group). Nitrogen sources may include nitrogen gas (N₂), ammonia (NH₃), hydrazine (N₂H₂), amines (RₓNR′₃₋ₓ, where x is an integer from 0 to 3, and each R and R′ is independently any organic or hetero-organic radical group), amides ((RCO)ₓNR′₃₋ₓ, where x is 0 to 3 and each R and R′ is independently any organic or hetero-organic radical group), imides (RCONCOR′, where each R and R′ is independently any organic or hetero-organic radical group), enamines (R₁R₂C═C₃NR₄R₅, where each R₁-R₅ is independently any organic or hetero-organic radical group), and nitrogen atoms and radicals.

FIG. 2 depicts an enlarged view of the intrinsic type silicon containing layer 108 according to one embodiment of the present invention. The intrinsic type silicon containing layer 108 is deposited as multiple layers comprising different crystalline fraction and silicon lattice phases. In one embodiment, the intrinsic type silicon containing layer 108 contains alternating layers of a microcrystalline/nanocrystalline silicon layer 108a and an amorphous silicon layer 108b repeatedly deposited until a desired film thickness 202 is reached. Generally, the microcrystalline/nanocrystalline silicon layer has distinct crystal grain size. As the grain of the microcrystalline/nanocrystalline silicon layer continues to grow during deposition, the silicon atoms may aggregate to form large crystalline clusters, during the growth, the grain boundaries may form between clusters. Defects, precipitate, void, and impurities accumulate and pile up at the grain boundaries, which may adversely impact the electrical performance of the resultant film. For example, as the grain boundary volume density increases, more charge carriers generated in the solar cell may recombine at the grain boundaries, thereby reducing the photocurrent generated in the solar cell. Typically, thick microcrystalline/nanocrystalline silicon layers have relatively high crystalline fraction. The defect formation and electron recombination rate in such films, however, may be adversely increased as the density of grain boundaries formed in the microcrystalline/nanocrystalline silicon layers are increased.

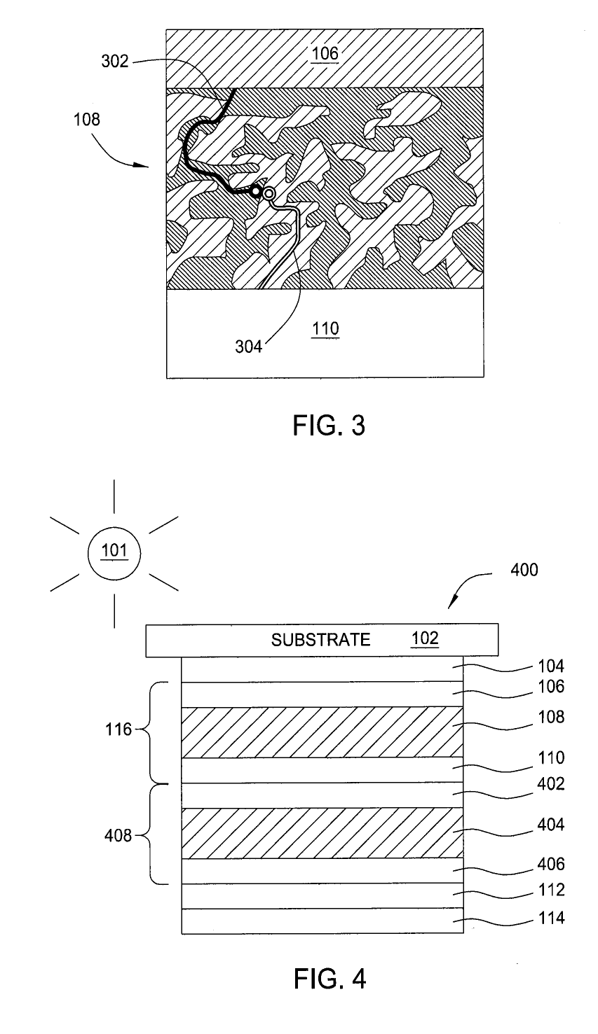

Therefore in one embodiment, an alternating film structure including the microcrystalline/nanocrystalline silicon layer 108a and the amorphous silicon layer 108b is provided to produce a film having a desired crystalline fraction as well as maintaining a low grain boundary density, while maintaining desirable small amount of silicon grain/atom clusters. FIG. 3 depicts a grain morphology of the intrinsic type silicon containing layer 108 comprised of a combination of a microcrystalline/nanocrystalline silicon layer 108a and an amorphous silicon layer 108b. As grains 304 of the microcrystalline/nanocrystalline silicon layer 108a grows on the substrate 102 reaching to a desired size, grain boundaries 302 will also grow in size. As the grain reaches the desired size, the process parameters used to control the deposition of the microcrystalline/nanocrystalline silicon layer 108a are adjusted so that the amorphous silicon layer 108b is deposited. By so doing, the grain boundaries 302 formed between the grains of the microcrystalline/nanocrystalline silicon layer 108a are filled with amorphous silicon phase atoms. In this configuration, the defects of cluster structure of the grains 304 are passivated by the amorphous silicon layer formed around the grain boundaries 302, thus reducing carrier recombination and improving the electrical properties of the solar cell. Furthermore, the combination of the microcrystalline/nanocrystalline silicon layer 108a and the amorphous silicon layer 108b will absorb a broader spectrum of light than each layer separately, thereby increasing the formed solar cell's open circuit voltage, fill factor and energy conversion efficiency.

In one embodiment, at the start of the intrinsic type silicon containing layer deposition process, a relatively higher plasma power deposition process, e.g., plasma power greater than 300 mW/cm², may be provided to form the microcrystalline/nanocrystalline silicon layer 108a with a desired crystalline fraction. After the grains and thickness of the microcrystalline/nanocrystalline silicon layer 108a have reached to a predetermined size, the plasma process may be switched to a lower power, e.g., plasma power less than 300 mW/cm², to form the amorphous silicon layer 108b with smaller grains. Furthermore, other process parameters, such as gas flow rate, hydrogen dilution ratio (silane to hydrogen ratio), process pressure may be adjusted to switch growth of different silicon phrases. The process parameters, including but not limited to, plasma power, gas flow rate, hydrogen dilution ratio, and process pressure may be turned as needed so that interface between the microcrystalline/nanocrystalline silicon phase and amorphous silicon phase can be improved. In one exemplary embodiment, adjusting the flow ratio between the silane and hydrogen gas flow rate may change the film crystalline fraction as well. For example, high hydrogen dilution (e.g., high hydrogen gas flow rate vs. low silane gas flow rate in a gas mixture) during deposition may yield a high crystalline fraction formed in the resultant silicon containing film. In the embodiment wherein the resultant silicon containing layer is configured to form as microcrystalline/nanocrystalline silicon phase, a hydrogen to silane gas flow ratio (H₂/SiH₄ ratio) may be configured to be greater than 20. In the embodiment wherein the resultant silicon containing layer is configured to form as amorphous silicon phase, a hydrogen to silane gas flow ratio (H₂/SiH₄ ratio) may be configured to be less than 20

In one embodiment, the grain size of the microcrystalline/nanocrystalline silicon layer 108a is controlled from between about 100 Å to about less than 500 Å, such as greater than 100 Å. The thickness of each amorphous silicon layer 108b is controlled less than 200 Å and the thickness of each microcrystalline/nanocrystalline silicon layer 108a is controlled greater than 500 Å. In one embodiment, the microcrystalline/nanocrystalline silicon layer 108a has a thickness greater than that of the amorphous silicon layer 108b. For example, the microcrystalline/nanocrystalline silicon layer 108a is thicker than the amorphous silicon layer 108b to ensure continuous carrier conduction within the microcrystalline/nanocrystalline silicon layer. In one embodiment, the amorphous silicon layer 108b is not formed until the thickness and/or the grain size of the microcrystalline/nanocrystalline silicon layer 108a has reached to a desired size, such as greater than 500 Å. In one embodiment, the microcrystalline/nanocrystalline silicon layer 108a has a thickness between about 500 Å and about 1000 Å and the amorphous silicon layer 108b has a thickness between about 50 Å and about 200 In one exemplary embodiment, the microcrystalline/nanocrystalline silicon layer 108a has a thickness about 850 Å and the amorphous silicon layer 108b has a thickness about 50 Å.

In one embodiment, the microcrystalline/nanocrystalline silicon layer 108a and the amorphous silicon layer 108b may be repeatedly formed greater than 5 times until the bulk intrinsic type silicon containing layer 108 has reached a desired thickness, such as between about 500 nm and 2 μm. In one embodiment, the microcrystalline/nanocrystalline silicon layer 108a and the amorphous silicon layer 108b may be repeatedly formed between about 10 times and about 60 times, such as between about 20 times and about 50 times, for example about 40 times.

In an embodiment, the intrinsic type microcrystalline/nanocrystalline silicon layer 108a may be deposited by providing a gas mixture of silane and hydrogen gas in a flow rate ratio by volume of between about 20:1 and about 200:1. Silane gas may be provided at a flow rate between about 0.5 sccm/L and about 5 sccm/L. Hydrogen gas may be provided at a flow rate between about 40 sccm/L and about 400 sccm/L. Applying RF power between about 300 mW/cm² or greater, such as 450 mW/cm² or greater, at a chamber pressure between about 1 Torr and about 100 Torr, such as between about 3 Torr and about 20 Torr, or between about 4 Torr and about 12 Torr, will generally deposit an intrinsic type microcrystalline silicon layer having crystalline fraction between about 20 percent and about 80 percent, such as between 55 percent and about 75 percent, at a rate of about 200 Å/min or more, such as about 400 Å/min. In some embodiments, it may be advantageous to ramp the power density of the applied RF power from a first power density to a second power density during deposition.

In one embodiment, the intrinsic amorphous silicon layer 108b may be deposited by providing a gas mixture comprising hydrogen gas and silane gas in a flow rate ratio by volume of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 mW/cm² and about 250 mW/cm² may be provided to the showerhead. The pressure of the chamber may be maintained between about 0.1 Torr and 20 Torr, such as between about 0.5 Torr and about 5 Torr. The deposition rate of the intrinsic type amorphous silicon layer 108 will be about 100 Å/min or more. In an exemplary embodiment, the intrinsic type amorphous silicon layer 108 is deposited at a hydrogen to silane flow rate ratio by volume at about 12.5:1.

While performing the deposition process of forming the intrinsic type silicon containing layer 108 having the mixture of the microcrystalline/nanocrystalline silicon containing layer 108a and the amorphous silicon layer 108b, the RF power provided during the deposition process may be adjusted to form the intrinsic type silicon containing layer 108 with different silicon phases. For example, in the initial deposition stage, the RF power may be controlled to a first range at about 300 mW/cm² or greater to deposit the first microcrystalline/nanocrystalline silicon containing layer 108a. After the first microcrystalline/nanocrystalline silicon containing layer 108a has reached to a predetermined thickness, such as about 500 Å or greater, the RF power may be adjusted to a second range of less than 300 mW/cm² to form the first amorphous silicon layer 108b over the first microcrystalline/nanocrystalline silicon containing layer 108a. Similarly, after the first amorphous silicon layer 108b has reached to a predetermined thickness, such as about 50 Å or greater, the RF power may be adjusted back to the first range, such as about 300 mW/cm² or greater, to form a second microcrystalline/nanocrystalline silicon containing layer 108a. The adjustment of the RF power during deposition may be repeated until a predetermined number of pairs of microcrystalline/nanocrystalline silicon containing layer 108a and the amorphous silicon layer 108b are reached, such as greater than 20 repeated pairs of layers, or a desired thickness of intrinsic type silicon containing layer 108 is reached.

In the embodiment wherein the deposition of the mixture of the microcrystalline/nanocrystalline silicon containing layer 108a and the amorphous silicon layer 108b is controlled by adjusting gas flow ratio, the hydrogen dilution in the gas mixture may be switched from high to low to deposit the microcrystalline/nanocrystalline silicon containing layer 108a and the amorphous silicon layer 108b respectively. The gas flow ratio may be then switched back to high hydrogen dilution to commence a second deposition cycle that is used to form a microcrystalline/nanocrystalline silicon containing layer 108a and an amorphous silicon layer 108b until a desired number of microcrystalline/nanocrystalline silicon containing layers 108a and the amorphous silicon layers 108b are deposited, or a desired intrinsic type silicon containing layer 108 thickness is reached.

FIG. 4 depicts a schematic side-view of a tandem junction thin-film solar cell 400 according to one embodiment of the invention. In addition to the structure of the solar cell 100 depicted in FIG. 1, a second p-i-n junction 408 may be formed between the first p-i-n junction 116 and the second TCO layer 112. The second p-i-n junction 408 may have a p-type silicon containing layer 402, an intrinsic type silicon containing layer 404, and a n-type silicon containing layer 406. In one embodiment, the intrinsic type silicon containing layer 404 may be formed having the mixture of the microcrystalline/nanocrystalline silicon containing layer 108a and the amorphous silicon layer 108b, as depicted in FIGS. 1-2, to improve light conversion efficiency. In this configuration, the intrinsic type silicon containing layer 108 formed in the first p-i-n junction 116 may be deposited in the same or similar manner as the intrinsic type silicon containing layer 108 described with reference to in FIGS. 1-2. Alternatively, the intrinsic type silicon containing layer 108 formed in the first p-i-n junction 116 may be another suitable intrinsic type silicon containing layer, such as an intrinsic type amorphous silicon layer, an intrinsic type microcrystalline silicon layer or an intrinsic type polycrystalline silicon layer as desired.

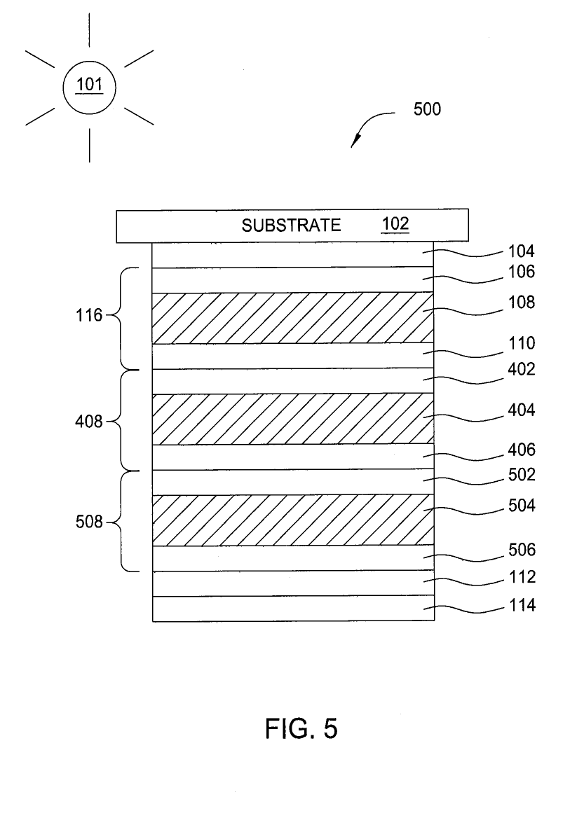

FIG. 5 depicts a schematic side-view of a triple junction thin-film solar cell 500 according to one embodiment of the invention. In addition to the structure of the solar cell 100, 400 depicted in FIGS. 1 and 4, respectively, a third p-i-n junction 508 may be formed between the second p-i-n junction 408 and the second TCO layer 112. The third p-i-n junction 508 may also have a p-type silicon containing layer 502, an intrinsic type silicon containing layer 504, and a n-type silicon containing layer 506. In one embodiment, the intrinsic type silicon containing layer 504 may have a mixture of microcrystalline/nanocrystalline silicon containing layers 108a and amorphous silicon layers 108b, as depicted in FIGS. 1-2 to improve light conversion efficiency. Alternatively, the mixture of the microcrystalline/nanocrystalline silicon containing layers 108a and the amorphous silicon layers 108b may be formed as the intrinsic type silicon containing layer 108 in the first p-i-n junction 116 and/or the intrinsic type silicon containing layer 404 in the second p-i-n junction 408. The mixture of the microcrystalline/nanocrystalline silicon containing layer 108a and the amorphous silicon layer 108b may be deposited in the same or similar manner as the intrinsic type silicon containing layer 108 described with referenced to FIGS. 1-2. Alternatively, the intrinsic type silicon containing layers 108, 404, 504 formed in the first, second and the third p-i-n junctions 116, 408, 508 may be another suitable intrinsic type silicon containing layer, such as an intrinsic type amorphous silicon layer, an intrinsic type microcrystalline silicon layer or an intrinsic type polycrystalline silicon layer, as desired. In an exemplary embodiment, the intrinsic type silicon containing layer 404 of the second p-i-n junction 408 may be the mixture of the microcrystalline/nanocrystalline silicon containing layers 108a and the amorphous silicon layers 108b, as depicted in FIGS. 1-2. The intrinsic type silicon containing layers 108, 504 of the first and the third p-i-n junction 116, 508 may be any suitable intrinsic type silicon containing layer, such as an intrinsic type amorphous silicon layer, an intrinsic type microcrystalline silicon layer or an intrinsic type polycrystalline silicon layer, as desired.

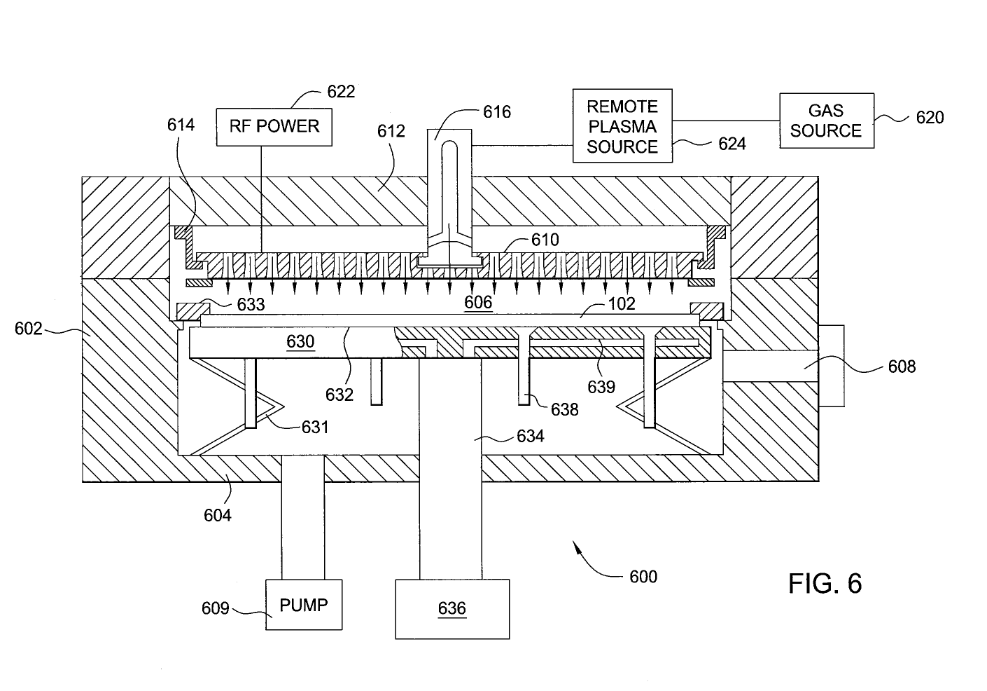

FIG. 6 depicts a schematic cross-section view of one embodiment of a plasma enhanced chemical vapor deposition (PECVD) chamber 600 in which one or more films of a thin-film solar cell, such as the solar cells of FIGS. 1-5 may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 600 generally includes walls 602, a bottom 604, and a showerhead 610, and substrate support 630 which define a process volume 606. The process volume is accessed through a valve 608, such that the substrate 102, may be transferred in and out of the chamber 600. The substrate support 630 includes a substrate receiving surface 632 for supporting a substrate and stem 634 coupled to a lift system 636 to raise and lower the substrate support 630. A shadow ring 633 may be optionally placed over periphery of the substrate 102. Lift pins 638 are moveably disposed through the substrate support 630 to move a substrate 102 to and from the substrate receiving surface 632. The substrate support 630 may also include heating and/or cooling elements 639 to maintain the substrate support 630 at a desired temperature. The substrate support 630 may also include grounding straps 631 to provide RF grounding at the periphery of the substrate support 630.

The showerhead 610 is coupled to a backing plate 612 at its periphery by a suspension 614. The showerhead 610 may also be coupled to the backing plate by one or more center supports 616 to help prevent sag and/or control the straightness/curvature of the showerhead 610. A gas source 620 is coupled to the backing plate 612 to provide gas through the backing plate 612 and through the showerhead 610 to the substrate receiving surface 632. A vacuum pump 609 is coupled to the chamber 600 to control the process volume 606 at a desired pressure. An RF power source 622 is coupled to the backing plate 612 and/or to the showerhead 610 to provide a RF power to the showerhead 610 so that an electric field is created between the showerhead 610 and the substrate support 630 so that a plasma may be generated from the gases present between the showerhead 610 and the substrate support 630. Various RF frequencies may be used, such as a frequency between about 0.3 MHz and about 200 MHz. In one embodiment the RF power is provided to the showerhead 610 at a frequency of 13.56 MHz.

A remote plasma source 624, such as an inductively coupled remote plasma source, may also be coupled between the gas source and the backing plate. Between processing substrates, a cleaning gas may be provided to the remote plasma source 624 so that remote plasma is generated and provided to clean chamber components. The cleaning gas may be further excited by the RF power source 622 provided to the showerhead 610. Suitable cleaning gases include, but are not limited, to NF₃, F₂, and SF₆.

The deposition methods for one or more layers, such as one or more of the layers of FIGS. 1-5, may include the following deposition parameters in the process chamber of FIG. 6 or other suitable process chamber. A substrate having a plain surface area of 10,000 cm² or more, 40,000 cm² or more, or 55,000 cm² or more is provided to the chamber. It is understood that after processing the substrate may be cut to form smaller solar cells.

In one embodiment, the heating and/or cooling elements 639 may be set to provide a substrate support temperature during deposition of about 400° C. or less, such as between about 100° C. and about 400° C., for example between about 150° C. and about 300° C., or such as about 200° C.

The spacing during deposition between the top surface of a substrate 102 disposed on the substrate receiving surface 632 and the showerhead 610 may be between 400 mil and about 1,200 mil, such as between 400 mil and about 800 mil.

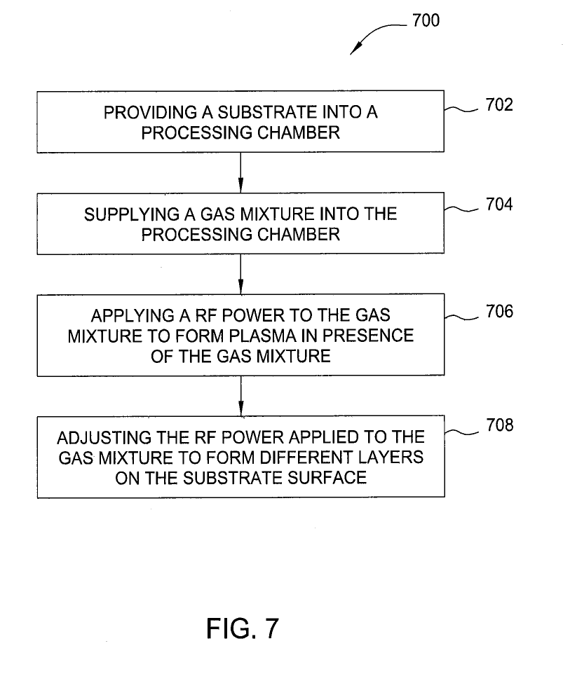

FIG. 7 depicts a flow diagram of a process sequence for fabricating an intrinsic type silicon containing layer 108, 404, 504 having mixed silicon phases in accordance with one embodiment of the present invention. The process 700 starts at step 702 by providing the substrate 102 into a processing chamber, such as the processing chamber 600 depicted in FIG. 6. The substrate 102 may have a p-type silicon containing layer, such as the p-type silicon containing layer 106 depicted in FIG. 1, formed thereon. In the embodiment wherein the solar cell is desired to be formed as multiple junctions, different numbers of structures of solar cell junctions, such as the junctions 116, 408, 508 depicted in FIGS. 1-5, may be formed on the substrate 102 as needed to form the desired multiple junctions.

At step 704, after the substrate 102 is transferred into the processing chamber, a gas mixture may be supplied to the processing chamber for depositing the intrinsic type silicon containing layer 108. The gas mixture supplied into the processing chamber may include a silicon containing gas, a hydrogen containing gas and an optional inert gas. In one embodiment, the silicon containing gas is SiH₄ and the hydrogen containing gas is H₂ and the optional inert gas is Ar or He. In one embodiment, the first layer deposited on the substrate 102 is a microcrystalline/nanocrystalline silicon layer, such as the silicon layer 108a depicted in FIGS. 1-2. The gas mixture supplied into the processing chamber to form the microcrystalline/nanocrystalline silicon layer may have a hydrogen to silane gas flow ratio by volume between about 200:1 and about 100:1. In one embodiment, the silane gas flow rate by volume is controlled at between about 0.5 sccm/L and about 5 sccm/L. Hydrogen gas may be provided at a flow rate by volume between about 40 sccm/L and about 400 sccm/L.

At step 706, an RF power may be supplied into the processing chamber to form a plasma using the gas mixture supplied at step 704. The RF power may be supplied at a first range, such as about 300 mW/cm² or greater, to form the microcrystalline/nanocrystalline silicon layer 108a on the substrate 102 until the microcrystalline/nanocrystalline silicon layer 108a has reached to a predetermined thickness, such as about 5000 Å. In one embodiment, the deposition time of the microcrystalline/nanocrystalline silicon layer 108a is between about 100 seconds and about 500 seconds.

At step 708, after the microcrystalline/nanocrystalline silicon layer 108a has reached to the predetermined thickness, the RF power supplied into the processing chamber may be adjusted to a second range, such as about less than 300 mW/cm², to deposit the amorphous silicon layer 108b until a predetermined thickness of the amorphous silicon layer 108b is reached. In one embodiment, the RF power during processing may be switched to a second range to deposit the amorphous silicon layer 108b for between about 20 seconds and about 200 seconds to form an amorphous silicon layer 108b having a thickness between about 50 Å and about 500 Å. When switching the RF power from the high first range to the low second range, other process parameters, such as gas mixture flow rate, gas flow ratio, or process pressure, may remain constant or be adjusted in accordance with the film property requirement of the resultant film. In one embodiment, other process parameters, such as gas mixture flow rate, gas flow ratio, or process pressure, are constant during deposition process, while only the RF power is adjusted. In another embodiment, the gas flow ratio may be switched from high hydrogen dilution, e.g., hydrogen to silane ratio greater than 20, to low hydrogen dilution, e.g., hydrogen to saline ratio less than 15.

After the amorphous silicon layer 108b is formed on the substrate 102, the RF power may be further adjusted between the first range of greater than 300 mW/cm² and the second range of less than 300 mW/cm² to respectively deposit additional microcrystalline/nanocrystalline silicon layers 108a and the amorphous silicon layers 108b until a desired number of the microcrystalline/nanocrystalline silicon layers 108a and the amorphous silicon layers 108b are deposited, or a desired total thickness of the intrinsic type silicon containing layer 108 is reached.

Thus, an apparatus and methods for forming an intrinsic type silicon containing layer with mixed silicon phases are provided. The intrinsic type silicon containing layer with mixed phases assists generating high photocurrent and high light absorption in the junction cells, thereby efficiently improving the photoelectric conversion efficiency and device performance of the PV solar cell.

While the foregoing is directed to embodiments of the present invention, other and further embodiments of the invention may be devised without departing from the basic scope thereof, and the scope thereof is determined by the claims that follow.

What is claimed is:

1. A photovoltaic device, comprising:
a first p-i-n junction cell formed on a substrate, wherein the p-i-n junction cell comprises:
a p-type silicon containing layer;
an intrinsic type silicon containing layer formed over the p-type silicon containing layer; and
a n-type silicon containing layer formed over the intrinsic type silicon containing layer, wherein the intrinsic type silicon containing layer comprises a first pair of microcrystalline layer and amorphous silicon layer.

2. The device of claim 1, wherein the intrinsic type silicon containing layer further comprises:
a second pair of microcrystalline silicon layer and amorphous silicon layer formed over the first pair of the microcrystalline silicon layer or the amorphous silicon layer.

3. The device of claim 2, further comprising:
a third pair of the microcrystalline silicon layer and amorphous silicon layer formed over the second pair of the microcrystalline silicon layer or the amorphous silicon layer.

4. The device of claim 1, wherein the microcrystalline silicon layer has grain size between about 50 Å and about 500 Å.

5. The device of claim 4, wherein the amorphous silicon layer is formed between the grain boundaries formed in the microcrystalline silicon layer.

6. The device of claim 1, wherein the microcrystalline silicon layer has a thickness between about 500 Å and about 1000 Å and the amorphous silicon layer has a thickness between about 50 Å and about 200 Å.

7. The device of claim 3, further comprising:
a fourth pair of microcrystalline silicon layer and the amorphous silicon layer formed over the third pair.

8. The device of claim 1, further comprising:
a second p-i-n junction cell formed over the first p-i-n junction cell, wherein the second p-i-n junction cell comprises:
a p-type silicon containing layer;
an intrinsic type silicon containing layer; and
a n-type silicon containing layer.

9. The device of claim 8, wherein the intrinsic type silicon containing layer of the second p-i-n junction is at least one of an intrinsic type amorphous silicon layer, an intrinsic type microcrystalline silicon layer, an intrinsic type polysilicon layer, or a combination of an intrinsic type amorphous silicon layer and an intrinsic type microcrystalline silicon layer.

10. A method for forming a photovoltaic device, comprising:
providing a substrate into a processing chamber;
depositing a multilayered intrinsic layer on the substrate by a method comprising:
supplying a gas mixture to the processing chamber;
applying a RF power to the processing chamber at a first power range to form a first intrinsic type microcrystalline silicon layer over the substrate; and
adjusting the RF power to a second power range to form a first intrinsic type amorphous silicon layer over the first intrinsic type microcrystalline silicon layer.

11. The method of claim 10, wherein depositing the multilayered intrinsic layer further comprises:
depositing a second intrinsic type microcrystalline silicon layer and a second intrinsic type amorphous silicon layer over the first amorphous silicon layer.

12. The method of claim 10, wherein depositing the multilayered intrinsic layer further comprises:
forming the first amorphous silicon layer over grain boundaries formed between the grains in the first microcrystalline silicon layer.

13. The method of claim 10, wherein applying the RF power at the first range further comprises:
applying the RF power greater than 300 mW/cm².

14. The method of claim 10, wherein adjusting the RF power at the second range further comprises:
adjusting the RF power less than 300 mW/cm².

15. The method of claim 10, wherein supplying the gas mixture further comprising:
providing a different gas composition ratio when depositing the first microcrystalline silicon layer and the first amorphous silicon layer.

16. A photovoltaic device having a p-i-n junction cell formed on a substrate, wherein the p-i-n junction includes a p-type silicon containing layer, an intrinsic type silicon containing layer and a n-type silicon containing layer, the photovoltaic device comprising:
an intrinsic type silicon containing layer having interleaved adjacent intrinsic microcrystalline silicon layers and intrinsic amorphous silicon layers.

17. The device of claim 16, wherein the intrinsic microcrystalline silicon layer has a grain size greater than 100 Å.

18. The device of claim 17, wherein grains of the intrinsic amorphous silicon layer are formed in grain boundaries of the intrinsic microcrystalline silicon layer.

19. The device of claim 16, wherein the intrinsic microcrystalline silicon layer has a thickness between about 500 Å and about 1000 Å, and the amorphous silicon layer has a thickness between about 50 Å and about 200 Å.

20. The device of claim 16, wherein the interleaved intrinsic microcrystalline silicon layers and intrinsic amorphous silicon layers comprises greater than 20 interleaved layers.
